(19) United States
(12) Patent Application Publication
(10) Pub. No.: US 2026/0324489 A1
(43) Pub. Date: Oct. 15, 2026

(54) FINE PITCH VERTICALLY CONNECTED SEMICONDUCTOR PACKAGES

(71) Applicant: Sandisk Technologies, Inc., Milpitas, CA (US)

(72) Inventors: Cong Zhang, Shanghai (CN); Xuyi Yang, Shanghai (CN); Han-Shiao Chen, Taichung (TW); Yiqin Huang, Shanghai (CN); Nagesh Vodrahalli, Milpitas, CA (US); Hsuan-Ling Chen, Taichung (TW); Fen Yu, Shanghai (CN)

(73) Assignee: Sandisk Technologies, Inc., Milpitas, CA (US)

(21) Appl. No.: 19/179,183

(22) Filed: Apr. 15, 2025

(51) Int. Cl. H10W 72/00; H10W 74/10; H10W 90/00; H10W 90/24

(52) U.S. Cl. CPC H10W 72/812; H10W 74/111; H10W 90/24; H10W 90/752; H10W 90/755

(57) ABSTRACT

A semiconductor device having semiconductor packages stacked above a substrate. Each semiconductor package has a stack of semiconductor dies in an offset configuration and a mold compound encapsulating the stack of dies. The dies may be memory dies. A set of electrical connections connect electrical contacts on the dies with electrical contacts on the substrate. Each electrical connection in the set has a segment extending along a vertical sidewall of the mold compound of at least one of the semiconductor packages.

### BACKGROUND

The strong growth in demand for portable consumer electronics is driving the need for high-capacity storage devices. Non-volatile semiconductor memory devices, such as flash memory storage cards, are becoming widely used to meet the ever-growing demands on digital information storage and exchange. Their portability, versatility and rugged design, along with their high reliability and large capacity, have made such memory devices ideal for use in a wide variety of electronic devices, including for example digital cameras, digital music players, video game consoles, PDAs and cellular telephones.

While many varied packaging configurations are known, flash memory storage cards may in general be fabricated as system-in-a-package (SiP) or multichip modules (MCM), where a plurality of die are mounted and interconnected on a small footprint substrate. The substrate may in general include a rigid, dielectric base having a conductive layer etched on one or both sides. Electrical connections are formed between the die and the conductive layer(s), and the conductive layer(s) provide an electric lead structure for connection of the die to a host device. Once electrical connections between the die and substrate are made, the assembly is then typically encased in a mold compound which provides a protective package.

To most efficiently use package footprint, it is known to stack semiconductor dies on top of each other. To provide access to bond pads on the semiconductor dies, the dies are stacked, either completely overlapping each other with a spacer layer in between adjacent dies, or with an offset. In an offset configuration, a die is stacked on top of another die so that the bond pads of the lower die are left exposed.

As semiconductor die become thinner, and to increase memory capacity in semiconductor packages, the number of dies stacked within a semiconductor package continues to increase. However, this can make for long bonds wire from the upper die down to the substrate. Long wire bonds are easily damaged or electrically shorted to other wire bonds. Moreover, larger numbers of semiconductor dies in a package can adversely affect yields.

Some conventional die stacks have “die overhang”, which refers to an upper die having an unsupported edge extending over a lower die Stacks with die overhang have been used to increase density. However, the upper die with the overhang is subject to stress during manufacture (especially during wire bonding). The upper die may bend during wire bonding, which could impair proper formation of the wire bonds. This stress could even potentially crack the upper die thereby resulting in yield loss. One possible way to reduce the amount of die bend, as well as the probability of die cracking, is to increase the thickness of the dies. However, increasing the die thickness comes at the expense of a taller stack.

### DESCRIPTION OF THE DRAWINGS

FIG. 1A depicts an embodiment of a fine pitch vertically connected semiconductor package.

FIG. 1B depicts a vertical sidewall of mold compound of a semiconductor package with segments of electrical connections.

FIG. 2A-2H depict different configurations for embodiments of fine pitch vertically connected semiconductor packages in a package stack.

FIG. 3 is a flowchart of an embodiment of fabricating a fine pitched vertically connected semiconductor package in package.

FIG. 4 shows a temporary carrier having temporary electrical contacts attached thereto.

FIG. 5 depicts stacks of semiconductor dies attached to the temporary carrier.

FIG. 6 depicts mold compound encapsulating the semiconductor dies.

FIG. 7 depicts removal of the temporary carrier from the semiconductor die stacks.

FIG. 8 depicts the DAF (Die Attach Film) and the DAF tape on the bottom of the semiconductor die stacks.

FIG. 9 depicts two semiconductor packages that have been formed from package dicing.

FIG. 10 depicts a vertical sidewall of the mold compound of one of the semiconductor packages.

FIG. 11 depicts one possible configuration in which four semiconductor packages have been picked and placed on a substrate.

FIGS. 12A and 12B depict left and right vertical sidewalls in which there are exposed wire bonds.

FIGS. 13A and 13B depict dispensing a “metallic nanoparticle composition” on the sidewalls and substrate.

FIGS. 14A and 14B depict further details of an embodiment of the electrical connections on the sidewalls of the mold compound.

FIG. 15 depicts several package stacks on a substrate.

FIG. 16 depicts an embodiment of a memory system having fine pitch vertically connected semiconductor packages.

FIGS. 17A and 17B depict two embodiments of layouts each having two package stacks.

### DETAILED DESCRIPTION

The present technology will now be described with reference to the figures, which in embodiments, relate to a semiconductor device including vertically stacked semiconductor packages, as well as methods for forming the semiconductor device. An embodiment includes a semiconductor device having semiconductor packages in a stack above a substrate. Each semiconductor package has a semiconductor dies in an offset configuration and a mold compound encapsulating the semiconductor dies. The semiconductor die may have memory cells. A set of electrical connections connect electrical contacts on the semiconductor dies with electrical contacts on the substrate. Each electrical connection in the set has a segment extending along a vertical sidewall of the mold compound of at least one of the semiconductor packages.

An embodiment includes a method for fabricating a semiconductor device including vertically stacked semiconductor packages. The method includes forming semiconductor packages, which includes the following for each semiconductor package. A stack of semiconductor dies are attached to a temporary carrier. The stack includes a semiconductor dies in an offset configuration. Each semiconductor die may include memory cells. The temporary carrier has temporary electrical contacts. For each semiconductor package, wire bonds are formed between one or more semiconductor dies in the stack and the temporary electrical contacts. The semiconductor dies are encapsulated with a mold compound such that the mold compound encapsulates the wire bonds. Portions of the mold compound are removed to thereby leave wire bond segments in the mold compound with exposed ends of the wire bonds on a sidewall of the mold compound. The semiconductor packages are then stacked on top of each other on a substrate having electrical contacts. The semiconductor packages may be aligned such that vertical sidewalls of the mold compound are aligned with each other. Electrical connections are formed between the exposed ends of the wire bonds and the electrical contacts on the substrate, including forming segments of the electrical connections on the vertical sidewalls of the mold compound of semiconductor packages. The segments connect to the exposed ends of the wire bonds. In an embodiment, 3D printing is used to form the segments of the electrical connections that are on sidewalls of the mold compound of the semiconductor packages. Note that the entire length of the electrical connections need not be formed from 3D printing. Rather segments of the electrical connections that are closest to the semiconductor dies may be formed within the mold compound that encapsulates the semiconductor dies.

Embodiments of the semiconductor device have a high density. Embodiments of the semiconductor device do not have die overhang. Therefore there are not any semiconductor dies with unsupported edge extending over a lower die. Consequently, the semiconductor dies can be made thinner without risking dies bend or cracking during wire bonding. Therefore, vertical thickness of the semiconductor device may be reduced without increasing yield loss. Moreover, the electrical connections between the semiconductor dies and the electrical contacts on the substrate can easily be fabricated without electrically shorting the electrical contacts to each other. For example, in an embodiment, 3D printing of the electrical contacts on the sidewalls of the mold compound reduces or eliminates risk of electrically shorting the electrical contacts to each other. Moreover, the segments of the electrical connections that are closest to the semiconductor dies and are formed within the mold compound that encapsulates the semiconductor dies are relatively short. Therefore, these short segments within the mold compound avoid problems of long wire bonds that are easily damaged or electrically shorted to other wire bonds.

It is understood that the present technology may be embodied in many different forms and should not be construed as being limited to the embodiments set forth herein. Rather, these embodiments are provided so that this disclosure will be thorough and complete and will fully convey the technology to those skilled in the art. Indeed, the technology is intended to cover alternatives, modifications and equivalents of these embodiments, which are included within the scope and spirit of the technology as defined by the appended claims. Furthermore, in the following detailed description of the present technology, numerous specific details are set forth in order to provide a thorough understanding of the present technology. However, it will be clear to those of ordinary skill in the art that the present technology may be practiced without such specific details.

The terms “top” and “bottom,” and “upper” and “lower” as may be used herein are by way of example and illustrative purposes only, and are not meant to limit the description of the technology inasmuch as the referenced item can be exchanged in position and orientation. Also, as used herein, the terms “substantially,” “approximately” and/or “about” mean that the specified dimension or parameter may be varied within an acceptable manufacturing tolerance for a given application. In one embodiment, the acceptable manufacturing tolerance is ±0.25%.

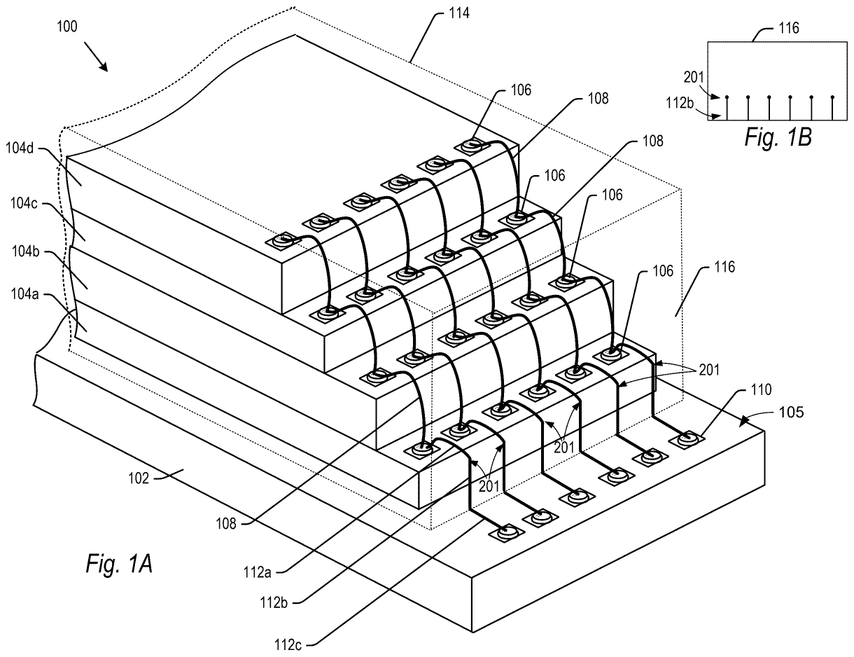

FIG. 1A depicts an embodiment of a fine pitch vertically connected semiconductor package 100. The semiconductor package 100 resides above a substrate 102. The semiconductor package 100 has a stack of semiconductor dies 104a, 104b, 104c, 104d in an offset configuration. The offset configuration exposes die electrical contacts 106 on an edge of each semiconductor die 104. In this example the semiconductor package 100 has four semiconductor dies 104. However, there may be more than four semiconductor dies 104 stacked in a package 100. For example, additional semiconductor dies 104 may be added on top of semiconductor dies 104d. Numerous examples are provided herein in which there are eight semiconductor dies in the package 100; however, there may be more or fewer than eight semiconductor dies in the package 100. In an embodiment, the semiconductor dies contain memory cells such as, for example, NAND memory cells. Wire bonds 108 connect the die electrical contacts 106 of one semiconductor die 104 to the die electrical contacts 106 of another semiconductor die 104. The die electrical contacts 106 of semiconductor die 104a are connected to substrate electrical contacts 110 on the substrate 102 by electrical connections 112. The substrate electrical contacts 110 on the substrate 102 may include, but are not limited to, contact pads, contact fingers, etc. The electrical connections 112 are depicted as having three segments 112a, 112b, 112c. A mold compound 114 encapsulates the semiconductor dies 104. The mold compound 114 is depicted by dashed lines around the semiconductor dies 104. Wire bond segments 112a are within the mold compound 114. In an embodiment, segments 112b are formed on a sidewall of the mold compound 114. In this example, the segments 112b are formed on a vertical sidewall 116 of the mold compound 114. Herein the sidewall 116 will be referred to as a “vertical sidewall” due to its physical relationship with the upper surface 105 of the substrate 102, which will be referred to as a “horizontal surface”.

Segments 112c connect to the electrical contacts 110 on the substrate 102. The segments 112a may be similar to the wire bonds 108. However, in an embodiment, segments 112b and 112c are formed by 3D printing. In an embodiment segments 112b and 112c are formed by dispensing a metallic nanoparticle composition. The metallic nanoparticle composition may include, but is not limited to, silver (Ag) nanoparticles, gold (Au) nanoparticles, and copper (Cu) nanoparticles. Note that the semiconductor package 100 does not have die overhang. Therefore, the semiconductor dies 104 can be relatively thin while still avoiding excessive die bending or cracking during fabrication (e.g., during formation of the wire bonds 108, and electrical connections 112).

FIG. 1B depicts the vertical sidewall 116 of mold compound 114 of a semiconductor package 100 with segments 112 of electrical connections. The ends 201 of segments 112a are depicted on the vertical sidewall 116 of mold compound 114. Recall that segments 112a are within the mold compound 114; however, the ends 201 of the segments 112a are exposed in the vertical sidewall 116 of mold compound 114. Segments 112b are also depicted on the vertical sidewall 116 of mold compound 114. In an embodiment, segments 112b are formed by 3D printing. Segments 112c are not depicted in FIG. 1B, but in an embodiment are also formed by 3D printing. In this simplified example in FIGS. 1A and 1B the ends 201 of segments 112a all derive from wire bonds connected to semiconductor die 104a. However, wire bonds from any of the semiconductor die 104a could have segments with ends at the vertical sidewall 116 of mold compound 114. Also, in this simplified example the segments 112b on the vertical sidewall 116 only extend upward to about the lowest semiconductor die 104a. However, there may be electrical segments on the vertical sidewall 116 at a higher level of the semiconductor package 100. For example, with reference again to FIG. 1A, whereas segments 112a connect to die electrical contacts 106 on semiconductor die 104a, similar segments 112a could connect to any of the other semiconductor die 104, 104c, 104d. Also, in this simplified example in FIGS. 1A and 1B, the semiconductor package 100 resides directly on the substrate 102. However, semiconductor packages 100 may be stacked on the substrate 102 such that the segments 112b may extend across the vertical sidewall 116 of more than one semiconductor package 100 thereby providing for relatively long vertical segments 112b.

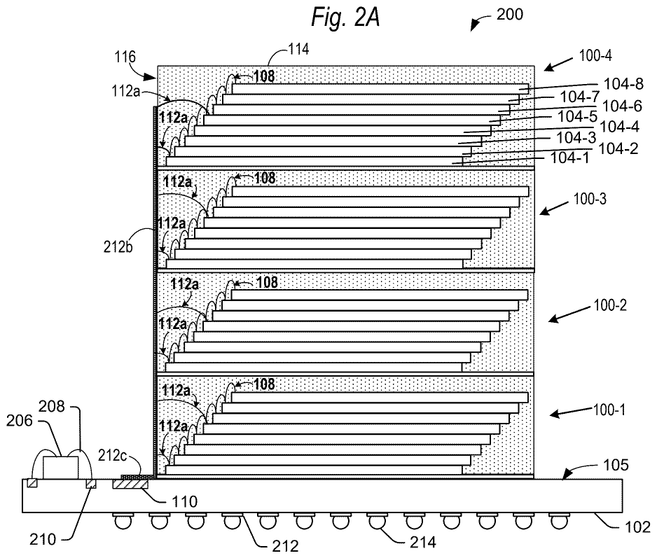

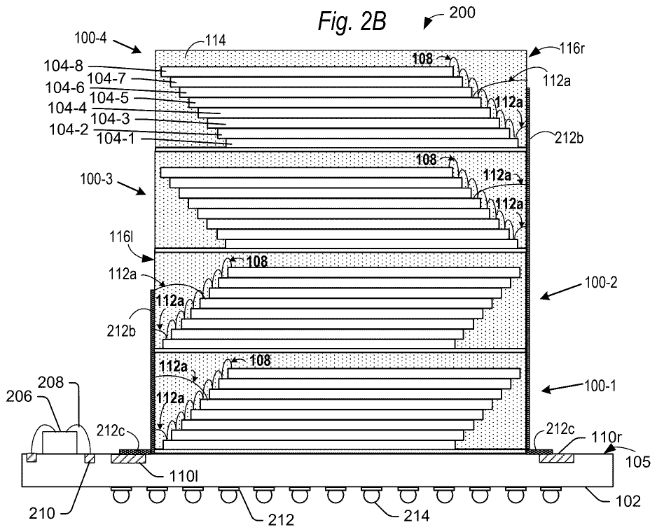

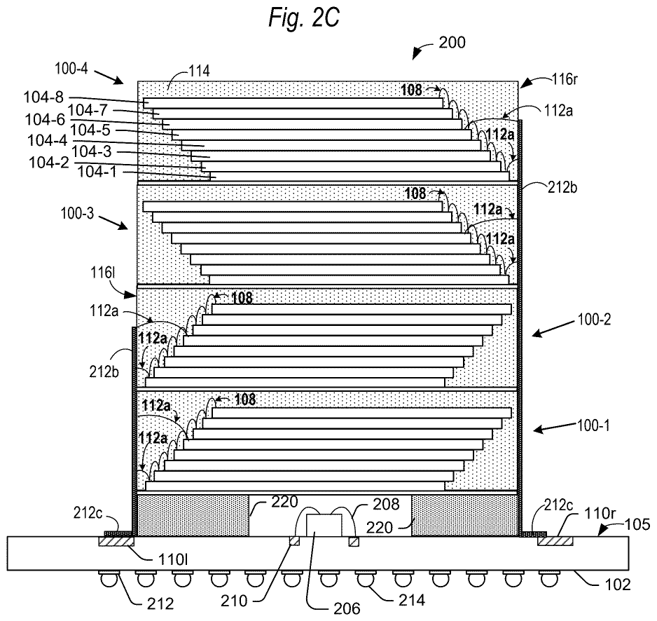

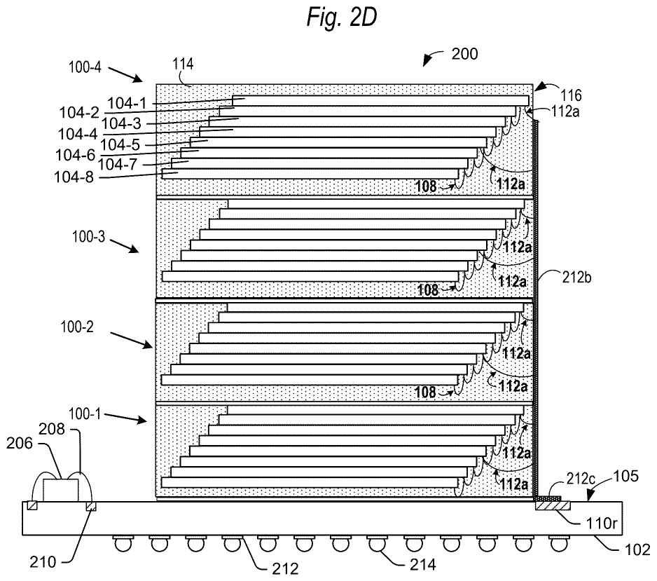

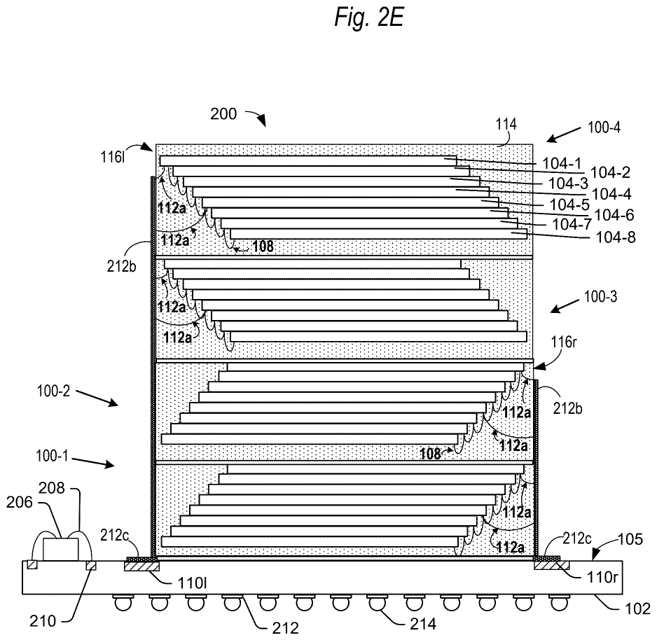

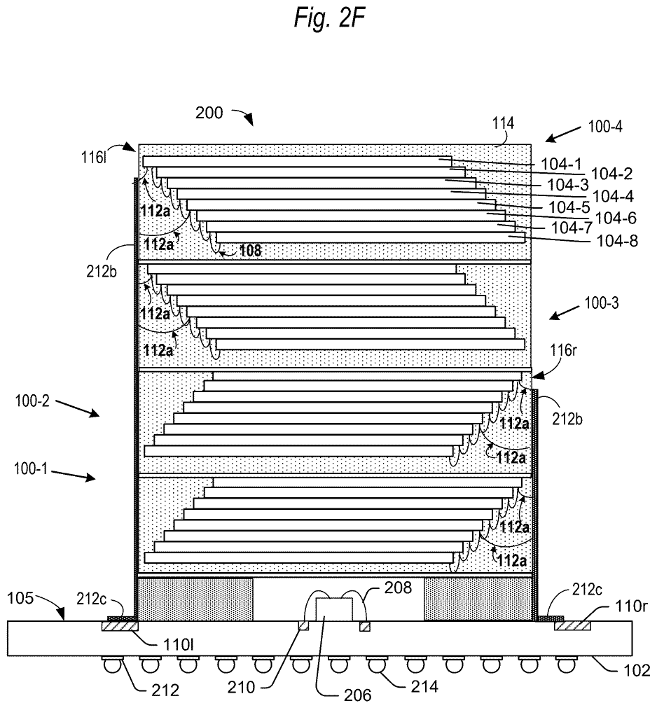

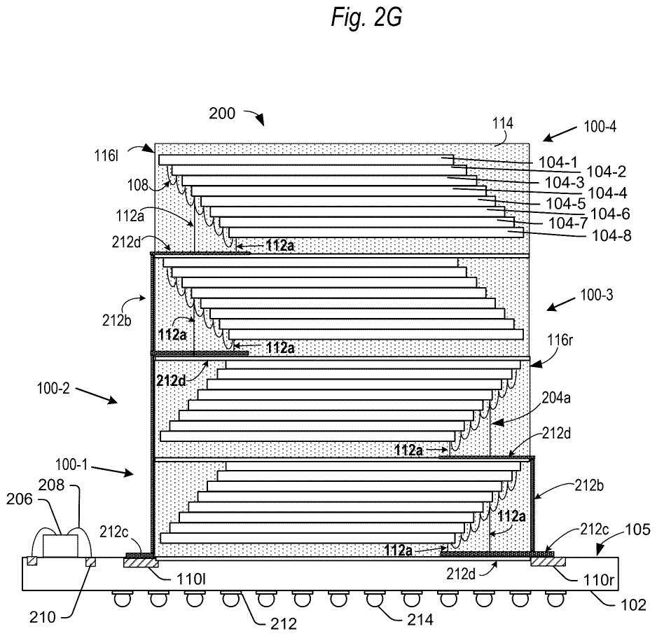

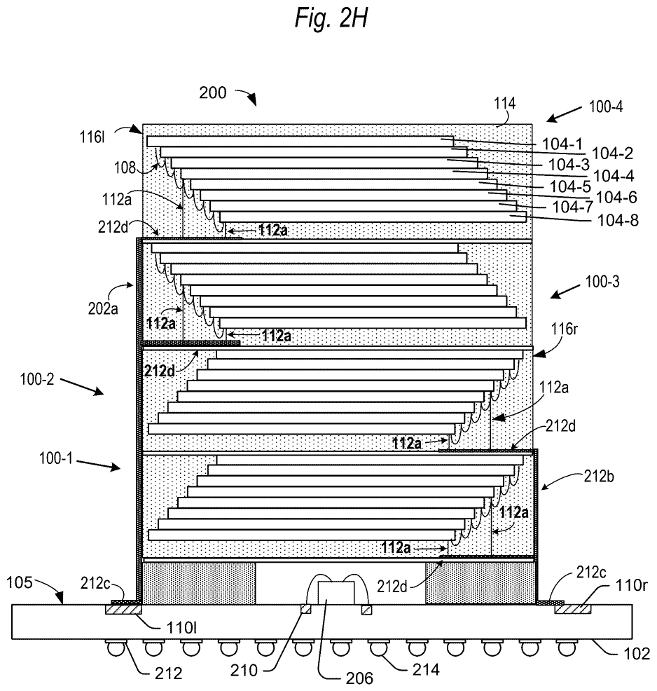

FIG. 2A-2H depict different configurations for embodiments of fine pitch vertically connected semiconductor packages in a package stack. FIG. 2A depicts an embodiment of fine pitch vertically connected semiconductor packages 100 with electrical connections on one side of a package stack 200. A number of semiconductor packages 100-1, 100-2, 100-3, 100-4 are stacked in the package stack 200 above a substrate 102. In this example, as well as many other examples herein, there are four semiconductor packages 100 in a package stack 200. However, there may be more or fewer than four semiconductor packages 100 in the package stack 200. Each semiconductor package 100 has a stack of semiconductor dies 104 in an offset configuration. For example, package 100-4 has semiconductor dies 104-1, 104-2, 104-3, 104-4, 104-5, 104-6, 104-7, and 104-8. The other semiconductor packages 100-1, 100-2, 100-3 also have semiconductor dies 104 in an offset configuration. In this example each semiconductor package 100 has eight semiconductor dies 104. However, in this and other examples with eight semiconductor dies, there may be more or fewer than eight semiconductor dies 104 stacked in a semiconductor package 100. In an embodiment, the semiconductor dies 104 contain memory cells such as, for example, NAND memory cells. The semiconductor package 100 in FIG. 1A is a perspective view of a simplified example of the lowest semiconductor package 100-1 in the package stack 200. Note that FIG. 1A shows only four of the semiconductor dies 104.

The offset configuration of the semiconductor packages 100 exposes electrical contacts (see FIG. 1A) on an edge of each semiconductor die 104. However, these electrical contacts are not depicted in FIG. 2A. Wire bonds 108 connect the electrical contacts (not depicted in FIG. 2A) of one semiconductor die 104 to the electrical contacts of another semiconductor die 104. Each wire bond segment 112a within the mold compound 114 connects to an electrical contact on an edge of a semiconductor die 104. The wire bond segments 112a form part of the electrical connections between the semiconductor dies 104 and the substrate electrical contacts 110 on the substrate 102. The substrate electrical contacts 110 may include, but are not limited to, contact pads, contact fingers, etc. Note that the substrate electrical contact 110 in FIG. 2A represents one of many electrical contacts 110 on the substrate 102. Similar to the embodiment in FIG. 1A, the electrical connections between the die contacts 106 on semiconductor dies 104 and electrical contacts 110 on the substrate 102 have three segments. A mold compound 114 encapsulates the semiconductor dies 104. Wire bond segments 112a are within the mold compound 114. Two example wire bond segments 112a (connected directly to semiconductor dies 104-1 and 104-5) are depicted for each semiconductor package 100. There will be more of these wire bond segments 112a in the mold compound 114. These wire bond segments 112a could directly connect to any of the semiconductor dies 104. The sidewall segments 112b (see FIGS. 1A, 1B) are collectively represented by sidewall segments 212b. In an embodiment, the sidewall segments 212b are formed on a vertical sidewall 116 of the mold compound 114. Substrate segments 212c connect to the electrical contacts 110 on the substrate 102. Substrate segments 212c represent the numerous substrate segments 112c (see FIG. 1A). In an embodiment, the sidewall segments 212b are printed on the sidewall 116 of the mold compound 114. In an embodiment, the substrate segments 212c are printed on the substrate 102. In an embodiment, the sidewall segments 212b are formed by dispensing a metallic nanoparticle composition on the sidewall 116 of the mold compound 114. In an embodiment, the substrate segments 212c are formed by dispensing the metallic nanoparticle composition on the substrate and/or contacts 110. The metallic nanoparticle composition may include, but is not limited to, silver (Ag) nanoparticles, gold (Au) nanoparticles, and copper (Cu) nanoparticles. Further details of dispensing a metallic nanoparticle composition are discussed below.

An Application Specific Integrated Circuit (ASIC) 206 resides on the substrate 102. The ASIC 206 has wire bonds 208 connected to ASIC electrical contacts 210 on the substrate 102. In the embodiment of FIG. 2A, the ASIC 206 resides to one side of the package stack 200. The substrate also has electrical contacts 212 and solder balls 214 on a surface opposite the package stack 200.

FIG. 2B depicts an embodiment of fine pitch vertically connected semiconductor packages 100 having electrical connections on two vertical sides of a package stack 200. Similar aspects to the package stack 200 of FIG. 2A will not be discussed in detail. The package stack 200 of FIG. 2B differs from the package stack 200 of FIG. 2A in that the semiconductor packages 100-3 and 100-4 in FIG. 2B are flipped relative to semiconductor packages 100-3 and 100-4 in FIG. 2B. Therefore, wire bond segments 112a of semiconductor packages 100-3 and 100-4 are exposed at a right vertical sidewall 116r of the mold compound 114, whereas wire bond segments 112a of semiconductor packages 100-1 and 100-2 are exposed at a left vertical sidewall 116l of the mold compound 114.

A mold compound 114 encapsulates the semiconductor dies 104. Wire bond segments 112a are within the mold compound 114. In an embodiment, the vertical segments 212b are formed on vertical sidewalls 116l, 116r of the mold compound 114. In this example, the vertical segments 212b for semiconductor packages 100-1 and 100-2 are formed on the left vertical sidewall 116l of the mold compound 114, whereas the segments 212b for semiconductor packages 100-3 and 100-4 are formed on the right vertical sidewall 116r of the mold compound 114. Horizontal segments 212c for semiconductor packages 100-1 and 100-2 connect to electrical contacts 110l to the left of the package stack 200 on the substrate 102. Horizontal segments 212c for semiconductor packages 100-3 and 100-4 connect to electrical contacts 110r to the right of the package stack 200 on the substrate 102.

FIG. 2C depicts an embodiment of fine pitch vertically connected semiconductor packages 100 having connections on two vertical sides of a package stack 200. Similar aspects to the package stack 200 of FIG. 2B will not be discussed in detail. The package stack 200 of FIG. 2C differs from the package stack 200 of FIGS. 2A and 2B in that the ASIC 206 resides below the package stack 200. Spacers 220 separate the package stack 200 from the substrate 102 and allow the ASIC 206 to reside below the package stack 200. The configuration of FIG. 2A may also be modified to have the ASIC 206 below the package stack 200. A configuration with the ASIC 206 below the package stack 200 will be referred to herein as an “embedded configuration.” In contrast, the configurations in FIGS. 2A and 2B with the ASIC 206 to a side of the package stack 200 will be referred to herein as a “side by side” configuration.

FIG. 2D depicts an embodiment of fine pitch vertically connected semiconductor packages 100 with electrical connections on one side of a package stack 200. The configuration in FIG. 2D is similar to the configuration in FIG. 2A, but with the stack of semiconductor packages 100-1, 100-2, 100-3, 100-4 in FIG. 2D flipped relative to the configuration in FIG. 2A. Therefore, the vertical segments 212b are on the right side of the package stack 200, as opposed to the left side of the package stack in FIG. 2A. Also, the horizontal segments 212c connect to contacts 110r on the right side of the stack 200.

FIG. 2E depicts an embodiment of fine pitch vertically connected semiconductor packages 100 with electrical connections on two sides of a package stack 200. The configuration in FIG. 2E is similar to the configuration in FIG. 2B, but with the stack of semiconductor packages 100-1, 100-2, 100-3, 100-4 in FIG. 2E flipped relative to the configuration in FIG. 2B.

FIG. 2F depicts an embodiment of fine pitch vertically connected semiconductor packages 100 with the ASIC 206 residing in the embedded configuration below the package stack 200. The configuration in FIG. 2F is similar to the configuration in FIG. 2E, but with the ASIC 206 residing in the embedded configuration below the package stack 200.

FIG. 2G depicts an embodiment of fine pitch vertically connected semiconductor packages 100 with electrical connections on two sides of a package stack 200. The configuration in FIG. 2G is similar to the configuration in FIG. 2E, but adds horizontal segments 212d between the semiconductor packages 100. For example horizontal segments 212d between semiconductor packages 100-3 and 100-4 connect to wire bond segments 112a, 112a that connect to dies in semiconductor package 200-4. Similarly, a horizontal segments 212d between semiconductor packages 100-2 and 100-3 connect to wire bond segments 112a, 112a that connect to dies in semiconductor package 200-3. The vertical segments 212b on the left vertical sidewall 116l connect horizontal segments 212d to substrate segments 212c. The routing of the electrical connections is completed to the substrate electrical contacts 110 by the substrate segments 212c on the substrate 102. The right side of the package stack 200 has similar horizontal segments 212d and substrate segments 212c for the lower two semiconductor packages 100-1 and 100-2.

FIG. 2H depicts an embodiment of fine pitch vertically connected semiconductor packages 100 with the ASIC 206 residing in the embedded configuration below the package stack 200. The configuration in FIG. 2H is similar to the configuration in FIG. 2G, but with the ASIC 206 residing in the embedded configuration below the package stack 200.

For each embodiment in FIG. 2A-2H the package stack 200 has high density. In each configuration, the left vertical sidewalls 116l of each semiconductor packages 100 are aligned with each other and the right vertical sidewalls 116r of each semiconductor packages 100 are aligned with each other to therefore provide for a small horizontal footprint. Also, the semiconductor dies 104 may be relatively thin to therefore provide for a small vertical stack height. In each configuration, each semiconductor packages 100-2, 100-3, 100-4 above the lowest semiconductor package 100-1 contains semiconductor dies that are connected to substrate contacts 110 by vertical segments 212b along a vertical sidewall of a semiconductor package 100 below the particular semiconductor package (100-2, 100-3, 100-4). Therefore, long wire bonds are not needed between semiconductor packages 100-2, 100-3, 100-4 and the substrate contacts 110.

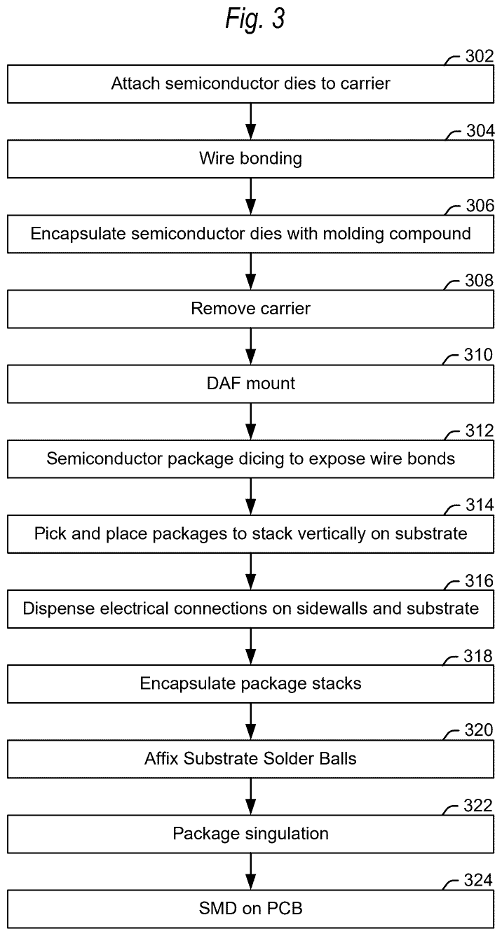

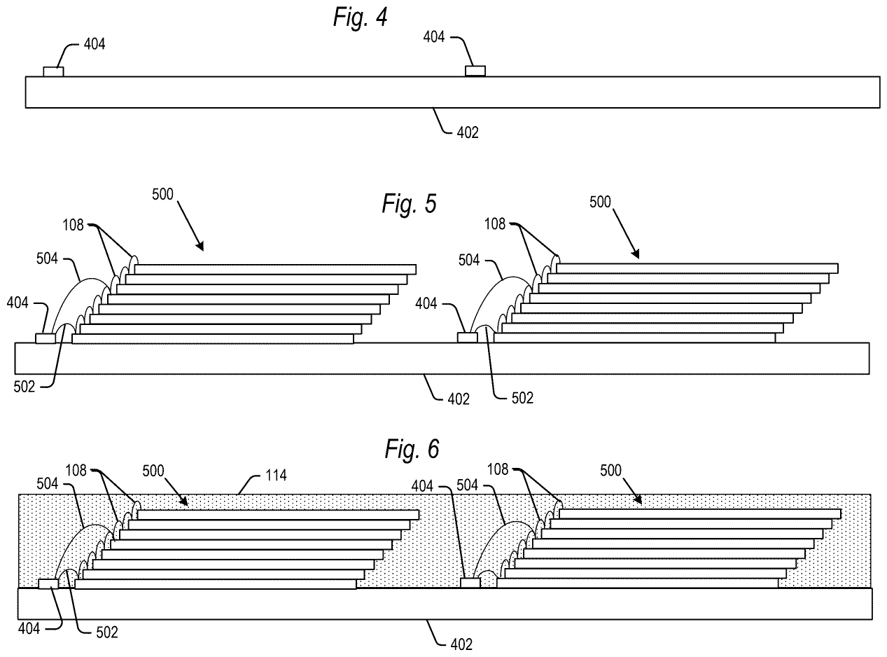

An embodiment of the present technology will now be explained with reference to the flowchart of FIG. 3 and the side perspective views of FIGS. 4 through 16. Step 302 includes attaching semiconductor dies to one or more carriers. Note that more than one carrier could be used to accommodate a relatively large number of semiconductor dies in the final package stack 200. Step 304 includes wire bonding. Step 304 includes forming temporary wire bonds between the semiconductor dies and temporary electrical contacts on the one or more carriers. The temporary electrical contacts may be contact fingers, contact pads, etc. FIG. 4 shows a temporary carrier 402 having temporary electrical contacts 404 attached thereto. These temporary electrical contacts 404 are only temporary structures and will not be part of the final product (e.g., memory system). In an embodiment, the temporary electrical contacts 404 have the same (or a very similar) configuration as the final electrical contacts. In an embodiment, the temporary electrical contacts 404 have the same number of contacts as the final electrical contacts 100. In an embodiment, the temporary electrical contacts 404 have the same pitch as the final electrical contacts 100.

FIG. 5 depicts stacks 500 of semiconductor dies attached to the temporary carrier 402. Each semiconductor die stack 500 will become the semiconductor dies 104 of a semiconductor package 100. There are two types of wire bonds depicted in FIG. 5. Wire bonds 108 connect die electrical contacts 106 on the semiconductor dies 104 to each other. These wire bonds 108 may remain in place and be a part of the final product (e.g., memory system. Another types of wire bond (502, 504) depicted in FIG. 5 are not the final wire bonds. Each wire bond 502, 504 directly connects between one of the electrical contacts of a semiconductor die 104 and a temporary electrical contact 404. The temporary electrical contact 404 provide a means to secure the wire bonds 502, 504. Later in the process, portions of wire bonds 502, 504 that connect to the temporary electrical contact 404 will be removed. However, portions of wire bonds 502, 504 that connect to the semiconductor dies will remain in place. Also note that FIG. 4-9 depict just two of the semiconductor die stacks 500 involved in the formation of the package stack 200. Similar processing is performed for other semiconductor die stacks 500 on the same carrier 402 or other carriers.

Step 306 includes encapsulating the semiconductor dies with mold compound. FIG. 6 depicts the mold compound 114 encapsulating the semiconductor dies of the semiconductor packages. The mold compound 114 also encapsulates wire bonds 502, 504, as well as wire bonds 108. Segments 112b will be printed on sidewalls of the mold compound 114 at a later stage of the process. Therefore, mold compounds having a smoother surface may be selected for better results when printing segments on the electrical connections 112 on the mold compound 114. Mold compound may include for example solid epoxy resin, Phenol resin, fused silica, crystalline silica, carbon black and/or metal hydroxide. Such mold compounds are available for example from Sumitomo Corp. and Nitto-Denko Corp., both having headquarters in Japan. Other mold compounds from other manufacturers are contemplated.

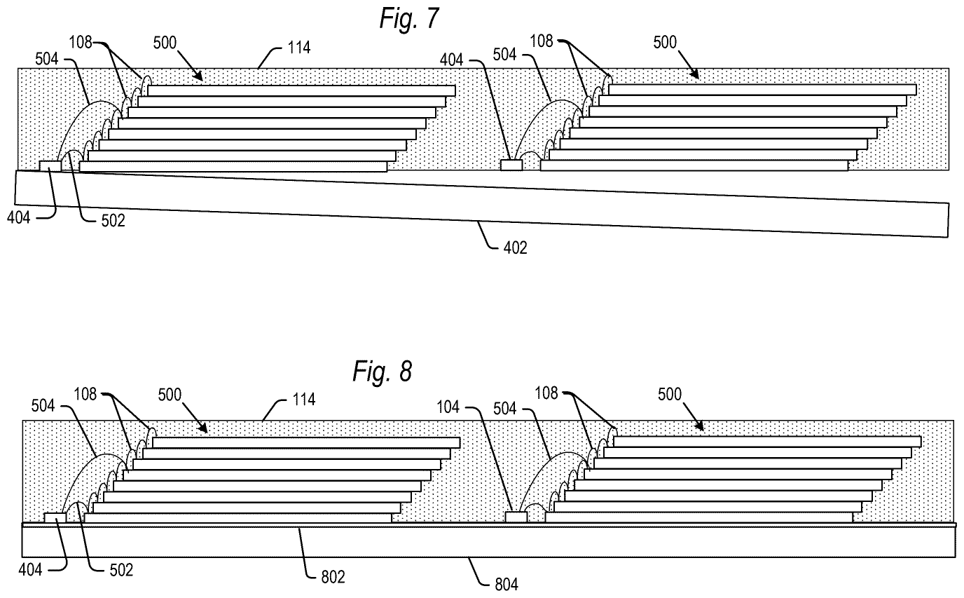

Step 308 includes removing the temporary carrier. FIG. 7 depicts removal of the temporary carrier 402 from the semiconductor stacks 500.

Step 310 includes DAF (Die Attach Film) mount. FIG. 8 depicts the DAF 802 and the DAF tape 804 on the bottom of the semiconductor die stacks 500. Note that the process may be used to form a configuration such as in any of FIG. 2A-2F, although the process is not limited to these configurations. Alternatively, the DAF 802 and the DAF tape 804 may be mounted on top of the semiconductor die stacks 500 to form a configuration such as in FIG. 2g or 2h.

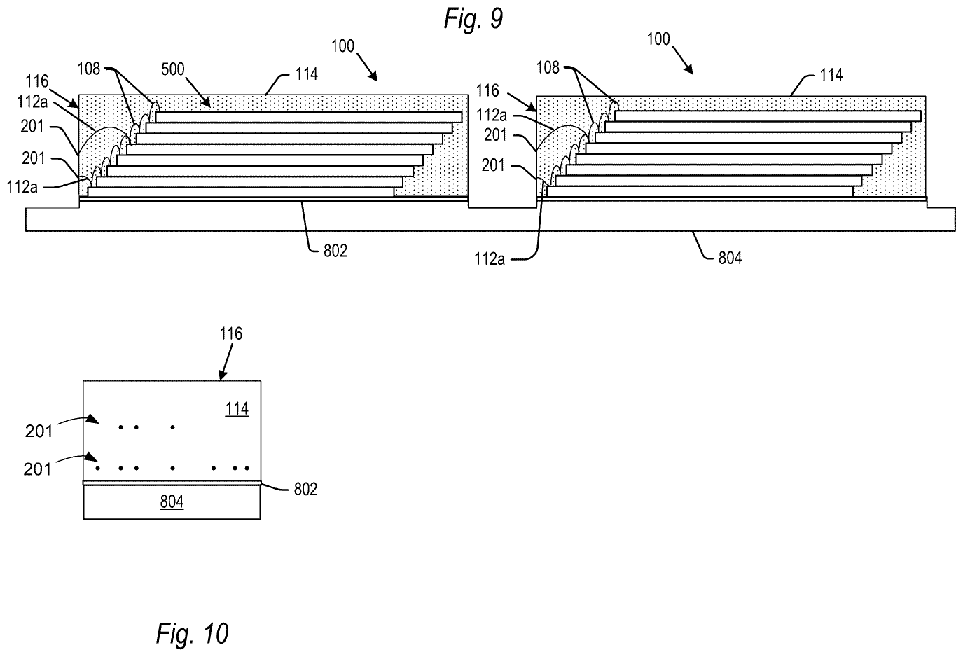

Step 312 including semiconductor package dicing to expose wire bond segments. FIG. 9 depicts that two semiconductor packages 100 have been formed from package dicing. The dicing has cut vertical sidewalls 116 into the mold compound 114. Wire bond segments 112a are what remains of wire bonds 502, 504 with the ends 201 of wire bond segments 112a being exposed in the vertical sidewalls 116 of the mold compound 114. FIG. 10 depicts a vertical sidewall 116 of the mold compound 114 of one of the semiconductor packages 100. Examples of ends 201 of the wire bond segments 112a are depicted in the vertical sidewall 116. This pattern is for purpose of illustration.

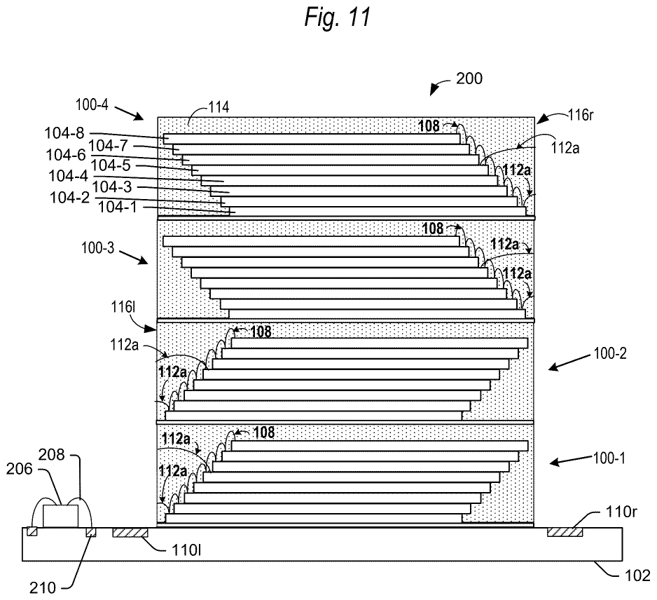

Step 314 includes picking and placing the semiconductor packages 100 into a vertical stack on a substrate. FIG. 11 depicts one possible configuration in which four semiconductor packages 100 have been picked and placed on a substrate 102. The substrate 102 may be an organic substrate. The substrate 102 may be formed of a core having a top conductive layer and a bottom conductive layer. The core may be formed of various dielectric materials such as for example, polyimide laminates, epoxy resins including FR4 and FR5, bismaleimide triazine (BT), and the like. The core may be ceramic or organic in alternative embodiments. The conductive layers surrounding the core may be formed of copper or copper alloys, plated copper or plated copper alloys, Alloy 42 (42Fe/58Ni), copper plated steel, or other metals and materials suitable for use on substrates. Conductance patterns are formed on one or both of the top and bottom surfaces of the substrate 102. The conductance pattern(s) may include electrical substrate contacts 110, 210 (e.g., contact pads, contact fingers, electrical traces, etc.).

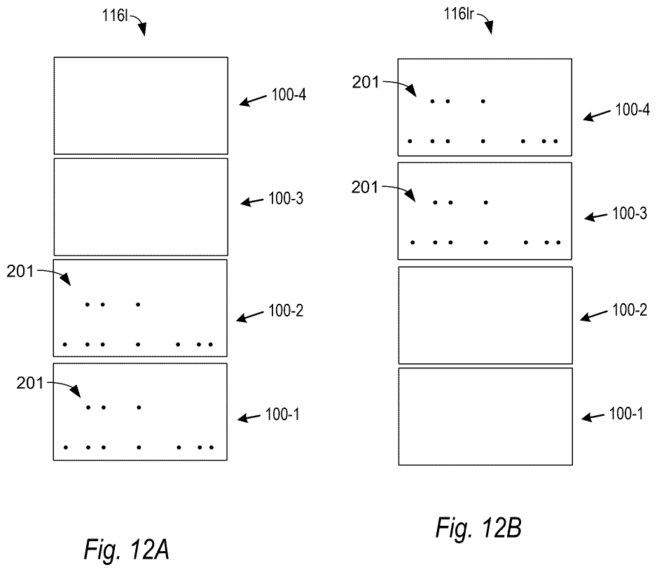

The semiconductor packages 100 may be stacked by module to module attach. This configuration in FIG. 11 is similar to the configuration in FIG. 2B; however, the electrical connections have not yet been formed on the left and right vertical sidewalls 116l, 116r. The ASIC 206 and its connections 208 to the electrical contacts 210 on the substrate 102 have already been formed. Other configurations such as those in FIGS. 2A, 2C, 2D, 2E, or 2F are also possible. FIGS. 12A and 12B depict the vertical sidewalls 116 of the mold compound 114 of one of the package stacks 200. FIG. 12A depicts the left vertical sidewall 116l in which there are exposed wire bonds 201 corresponding to semiconductor packages 100-1 and 100-2. FIG. 12B depicts the right vertical sidewall 116r in which there are exposed wire bonds 201 corresponding to semiconductor packages 100-3 and 100-4.

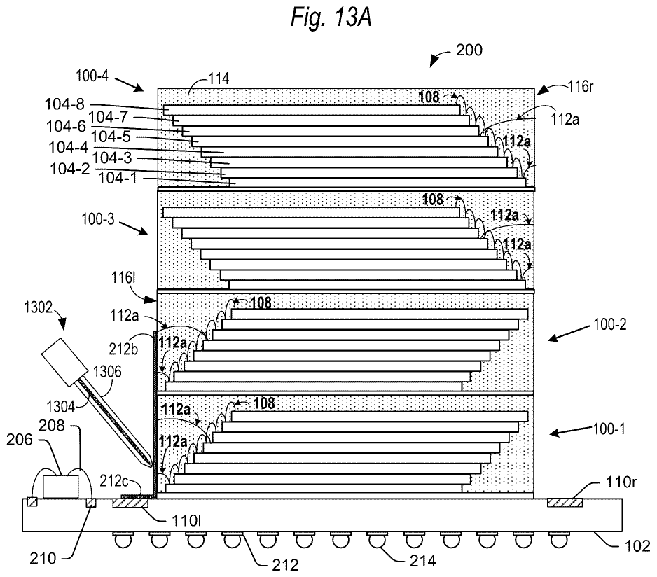

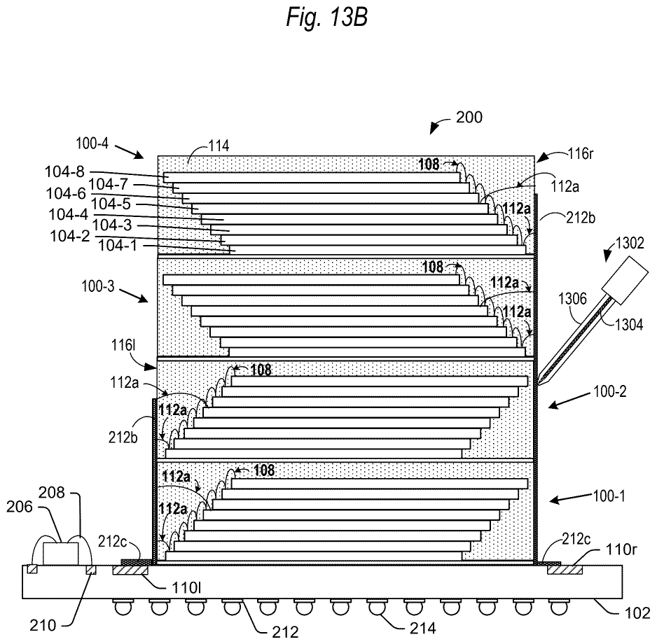

Step 316 includes dispensing electrical connections on the sidewalls of the mold compound 114 and the substrate 102. FIG. 13A depicts a dispensing tool 1302 being used to dispense a metallic nanoparticle composition 1304 on the left vertical sidewall 116l and the substrate 102. The metallic nanoparticle composition 1304 comprises metallic nanoparticles. The metallic nanoparticles may include, but are not limited to, silver (Ag) nanoparticles, gold (Au) nanoparticles, and copper (Cu) nanoparticles. The dispensing tool 1302 is part of a printing apparatus (not depicted in FIG. 13A) that is used to dispense the metallic nanoparticle composition 1304. The dispensing tool 1302 has a tube 1306 that used to direct the dispensing of the metallic nanoparticle composition 1304. The tube 1306 may be formed from materials including, but not limited to, glass or stainless steel.

The metallic nanoparticle composition 1304 may include a very high viscosity conductive paste, which enable printing of ultrafine features. For example, the printed segments 112b, 112c are about 10 micrometers wide in an embodiment. However, the printed segments 112b, 112c could be thinner or wider than 10 micrometers. The metallic nanoparticle composition 1304 may include a metallic nanoparticle paste composition. The metallic nanoparticle composition 1304 may include a metallic nanoparticle paste composition in glycol. As one example, the metallic nanoparticle composition 1304 may be Ag Nanopaste CL85 Conductive Silver Paste provided by XPTL, S.A., Wroclaw, Poland. As another example, the metallic nanoparticle composition 1304 may be Au Nanopaste 90 Conductive Gold Paste provided by XPTL, S.A., Wroclaw, Poland. However, the metallic nanoparticle composition is not limited to these examples. As one example, the dispensing apparatus used to dispense the metallic nanoparticle composition 1304 may be the Delta Printing System provided by XPTL, S.A., Wroclaw, Poland. However, the dispensing apparatus is not limited to this example.

Therefore, very fine pitch electrical connections 212b for semiconductor packages 100-1, 100-2 are formed in on the left vertical sidewall 116l of the package stack 200. Also, very fine pitch electrical connections 212c for semiconductor packages 100-1, 100-2 are formed in on substrate 102. FIG. 13B depicts the dispensing tool 1302 being used to dispense the metallic nanoparticle composition 1304 on the right vertical sidewall 116r and the substrate 102. Therefore, vertical segments 212b for semiconductor packages 100-3, 100-4 are formed on the right vertical sidewall 116r of the package stack 200. Similarly, substrate segments 212c for semiconductor packages 100-3, 100-4 are formed on the substrate 102 to the right of the package stack 200.

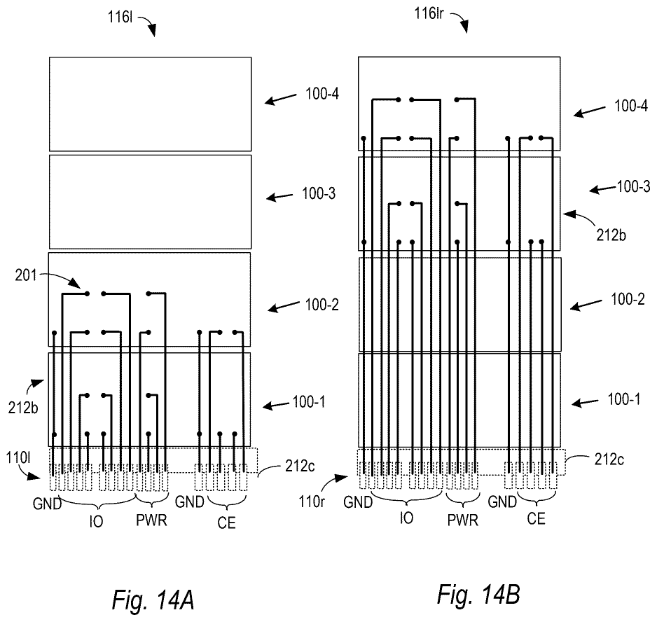

FIGS. 14A and 14B depict further details of an embodiment of the electrical connections on the sidewalls. FIG. 14A shows electrical connections 212b on the left vertical sidewall 116l in the regions associated with semiconductor packages 100-1, 100-2. FIG. 14B shows electrical connections 212b on the right vertical sidewall 116r in the regions associated with semiconductor packages 100-3, 100-4 (these electrical connections also extend through the sidewall associated with semiconductor packages 100-1, 100-2). For each side, the same pattern of exposed wired ends 201 from FIGS. 12A, 12B is again depicted. Dashed lines 212c show the substrate segments formed on the substrate 102 in order to connect to the substrate electrical contacts 110l, 110r. The substrate electrical contacts 110l, 110r are shown as dashed lines in FIGS. 14A, 14B. Also depicted is an example assignment of voltages/signals. In this simplified example, two lines for ground (GND), four lines for power (PWR), four lines for chip enable (CE) and eight lines for input/output (IO) are depicted for each side. However, there may be many more substrate electrical contacts 110l, 110r. As an example, there might be about 100 electrical contacts 110l, 110r on each side of the stack. The pitch for the electrical contacts 110l, 110r may be about 100 micrometers or even less than 100 micrometers. Note that many variations to the example routing of the electrical lines are possible.

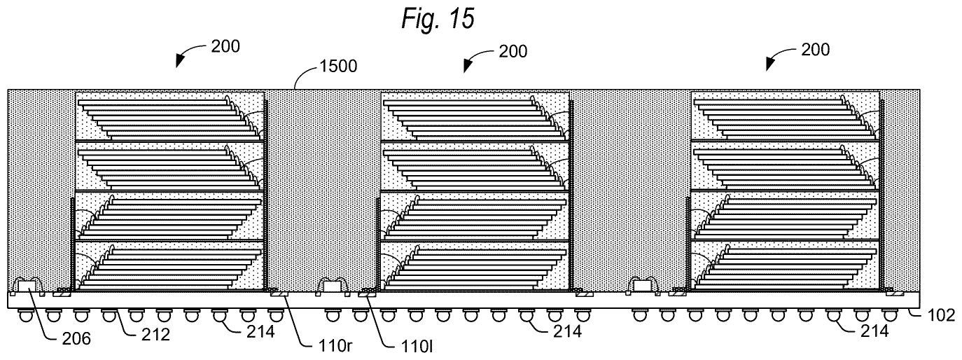

Step 318 includes encapsulating the package stacks 200 with a mold compound. Step 320 includes affixing solder balls to the substrate. FIG. 15 depicts several package stacks 200 on a substrate 102. A mold compound 1500 has been formed such that it encapsulates the package stacks 200. In an embodiment, the semiconductor device may be placed within a mold chase comprising upper mold plate and lower mold plate. Molten mold compound may then be injected into the mold chase to encase the package stacks 200 in a protective enclosure in for example a compression molding process. Mold compound 1500 may include for example solid epoxy resin, Phenol resin, fused silica, crystalline silica, carbon black and/or metal hydroxide. Such mold compounds are available for example from Sumitomo Corp. and Nitto-Denko Corp., both having headquarters in Japan. Other mold compounds from other manufacturers are contemplated. The mold compound may be applied according to other known processes, including by transfer molding or injection molding techniques. A lower surface of the substrate 102 includes electrical contact pads 212 for receiving solder balls 214. Other electrical connectors may be provided instead of solder balls 214. In various embodiments, multiple package stacks 200 on a substrate 102 may be used as a BGA (ball grid array) package. In various embodiments, multiple package stacks 200 on a substrate 102 may be used as an LGA (land grid array) package including contact fingers for removably coupling within a host device or the like.

Step 322 includes package singulation. The package stacks 200 may be singulated from each other by any of a variety of cutting methods including sawing, water jet cutting, laser cutting, water guided laser cutting, dry media cutting, and diamond coating wire cutting. While straight line cuts will define generally rectangular or square shaped semiconductor packages 100, it is understood that semiconductor package 100 may have shapes other than rectangular and square in further embodiments of the present technology.

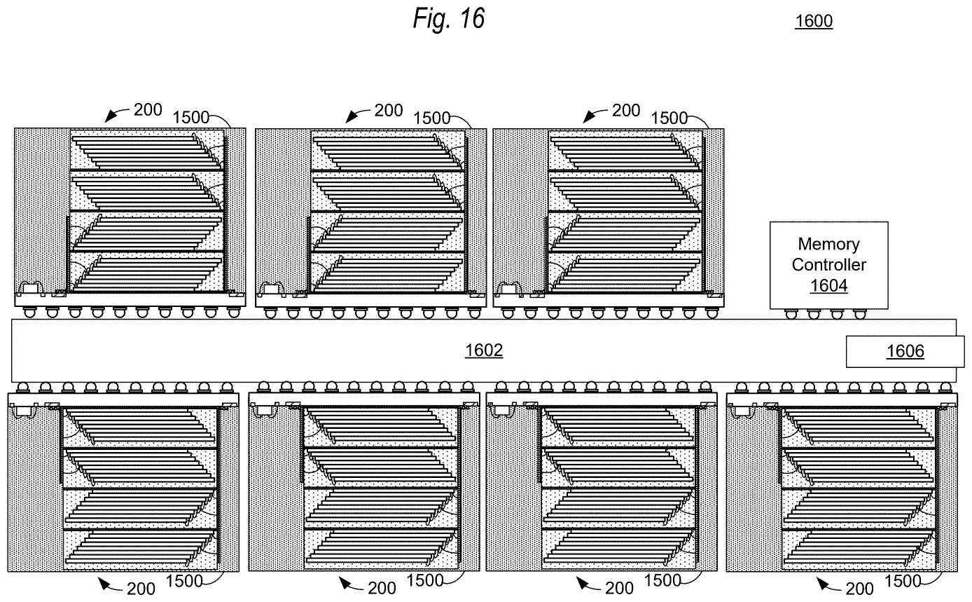

Step 324 includes assembly of a memory system. Step 324 includes attaching a number of the singulated package stacks 200 to a printed circuit board (PCB) or the like. A memory controller may also be attached to the PCB. In one embodiment, the memory system includes a solod state drive (SSD). However, other types of memory systems may be formed in step 324. FIG. 16 depicts an example memory system 1600 formed after step 324. A number of singulated package stacks 200 are attached to a printed circuit board (PCB) 1602 or the like. A memory controller 1604 is attached to the PCB 1602. The PCB 1602 has a memory system interface 1606 that may connect to a host system.

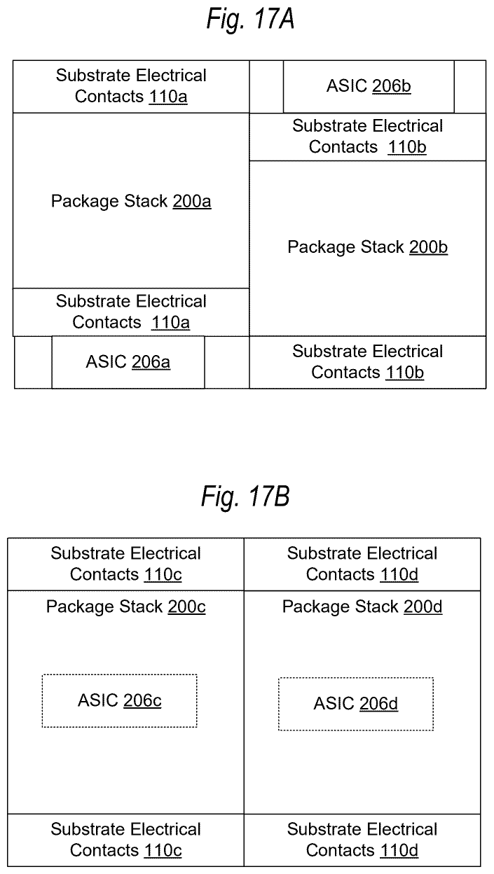

FIGS. 17A and 17B depict two embodiments of layouts each having two package stacks 200. FIG. 17A has two side by side package stacks 200a, 200b with the ASICs 206a, 206b to the side of their respective package stack (see, for example, FIGS. 2A, 2B, 2D, 2E, 2G). Substrate electrical contacts 110a and associated with package stack 200a and substrate electrical contacts 110b and associated with package stack 200b. FIG. 17B has two side by side package stacks 200c, 200d with the ASICs 206c, 206d in the embedded configuration (see, for example, FIGS. 2C, 2F, 2H). Substrate electrical contacts 110c and associated with package stack 200c and substrate electrical contacts 110d and associated with package stack 200d. The configurations in both FIG. 17A and FIG. 17B provide for high density and a small form factor. As one example if each package stack 200a has 32 semiconductor dies 104, then each configuration has 64 semiconductor dies 104. Each semiconductor die may contain a large number of memory cells, such as NAND memory cells (e.g., 2D or 3D NAND memory structures).

In summary, in one example, the present technology relates to a semiconductor device comprising a substrate having a plurality of substrate electrical contacts on a horizontal surface and a plurality of semiconductor packages in a stack above the substrate. Each semiconductor package comprises a plurality of stacked semiconductor dies having exposed die electrical contacts s. Each semiconductor package comprises a mold compound encapsulating the plurality of stacked semiconductor dies. The mold compound has vertical sidewalls. The semiconductor device has a set of electrical connections that connect a set of the die electrical contacts with respective contacts of the substrate electrical contacts. Each electrical connection in the set has a segment extending across a vertical sidewall of the mold compound of at least one of the semiconductor packages.

In a further aspect of the semiconductor device a first segment of a particular electrical connection extends from a first die electrical contact of a first semiconductor die in a first semiconductor package to a first vertical sidewall of the mold compound of the first semiconductor package. The first segment of the particular electrical connection resides within the mold compound of the first semiconductor package. A second segment of the particular electrical connection extends from the first segment along the first vertical sidewall of the mold compound of the first semiconductor package and one or more vertical sidewalls of the mold compound of a corresponding one or more additional semiconductor packages to the substrate.

In a further aspect of the semiconductor device, the second segment of the particular electrical connection also connects to an additional segment that resides within the mold compound of a second semiconductor package and connects to a second die electrical contact of a second semiconductor die of the second semiconductor package.

In a further aspect of the semiconductor device, a third segment of the particular electrical connection extends along the substrate from the second segment to a particular substrate electrical contact.

In a further aspect of the semiconductor device, a first segment of a particular electrical connection extends from a first die electrical contact of a first semiconductor die in a first semiconductor package to a first horizontal sidewall of the mold compound of the first semiconductor package. The first segment of the particular electrical connection resides within the mold compound of the first semiconductor package. A second segment of the particular electrical connection extends from the first segment along the first horizontal sidewall of the mold compound of the first semiconductor package to a vertical sidewall of the mold compound of a second semiconductor package immediately below the first semiconductor package in the stack. A third segment of the particular electrical connection extends from the second segment along the vertical sidewall of the mold compound of the second semiconductor package and along a vertical sidewall of the mold compound of zero or more additional semiconductor packages to the substrate. And a fourth segment of the particular electrical connection extends along the substrate from the third segment to a particular substrate electrical contact.

In a further aspect of the semiconductor device, a first subset of the segments of the electrical connections that extend across the vertical sidewalls reside on vertical sidewalls of the mold compound of a first subset of the semiconductor packages on a first side of the stack. A second subset of the segments that extend across the vertical sidewalls reside on vertical sidewalls of the mold compound of all of the semiconductor packages on a second side of the stack opposite the first side of the stack.

In a further aspect of the semiconductor device, the segments of the electrical connections that extend across the vertical sidewalls reside on vertical sidewalls of the mold compound on the same side of the stack.

In a further aspect of the semiconductor device further comprises a second mold compound that encapsulates the plurality of stacked semiconductor packages. The segments of the electrical connections that extend across the vertical sidewalls of the mold compound of the semiconductor packages are sandwiched between the mold compound of the semiconductor packages and the second mold compound.

In a further aspect, the semiconductor device further comprises a memory controller configured to control access to memory cells in the semiconductor dies.

In a further aspect, the semiconductor dies comprise non-volatile memory cells. And the stack of semiconductor packages resides directly on the substrate.

In a further aspect, the semiconductor dies comprises non-volatile memory cells. And the semiconductor device further comprises: a spacer residing on the substrate between the substrate and the stack of semiconductor packages to support the stack; and an application specific integrated circuit (ASIC) residing on the substrate in an embedded configuration below the stack of semiconductor packages.

In a further aspect, the semiconductor device further comprises an application specific integrated circuit (ASIC) residing on the substrate in an embedded configuration below to the stack of semiconductor packages.

An embodiment includes a method comprising forming a plurality of semiconductor packages. Forming each semiconductor package includes: attaching a stack of semiconductor dies to a temporary carrier, the stack comprising a plurality of semiconductor dies in an offset configuration with exposed die contacts, each semiconductor die comprising memory cells, the temporary carrier comprising temporary electrical contacts; forming wire bonds between the die contacts of one or more semiconductor dies in the stack and the temporary electrical contacts; encapsulating the semiconductor dies with a mold compound, wherein the mold compound encapsulates the wire bonds; and removing portions of the mold compound to thereby leave wire bond segments in the mold compound with exposed ends of the wire bonds on a first sidewall of the mold compound. The method further includes stacking the plurality of semiconductor packages on top of each other on a substrate having a plurality of substrate electrical contacts. The method further includes forming electrical connections between the exposed ends of the wire bonds and the substrate electrical contacts, including forming segments of the electrical connections on the first sidewalls of the mold compound of the plurality of semiconductor packages, the segments connecting to the exposed ends of the wire bonds.

An embodiment includes a memory system comprising a substrate having a plurality of substrate electrical contacts on a horizontal surface of the substrate. The memory system comprises package stacks residing on the horizontal surface of the substrate. Each package stack has a plurality of semiconductor packages above the substrate. Each semiconductor package comprises a plurality of semiconductor dies in an offset configuration exposing die electrical contacts. Each package stack has a first mold compound encapsulating the plurality of semiconductor dies of the package stack. The first mold compound having vertical sidewalls. Each semiconductor die comprises memory cells. The memory system comprises a second mold compound encapsulating the package stacks. The second mold compound has vertical sidewalls adjacent to the vertical sidewalls of the first mold compound. The memory system comprises electrical connections that connect the die electrical contacts on the semiconductor dies with the substrate electrical contacts, each electrical connection having a segment sandwiched between the vertical sidewall of the first mold compound and the vertical sidewall of the second mold compound.

The foregoing detailed description of the technology has been presented for purposes of illustration and description. It is not intended to be exhaustive or to limit the technology to the precise form disclosed. Many modifications and variations are possible in light of the above teaching. The described embodiments were chosen in order to best explain the principles of the technology and its practical application to thereby enable others skilled in the art to best utilize the technology in various embodiments and with various modifications as are suited to the particular use contemplated. It is intended that the scope of the technology be defined by the claims appended hereto.

We claim:

1. A semiconductor device, comprising:
a substrate having a plurality of substrate electrical contacts on a horizontal surface;
a plurality of semiconductor packages in a stack above the substrate, wherein each semiconductor package comprises a plurality of stacked semiconductor dies having exposed die electrical contacts, each semiconductor package comprises a mold compound encapsulating the plurality of stacked semiconductor dies, the mold compound having vertical sidewalls; and
a set of electrical connections that connect a set of the die electrical contacts with respective contacts of the substrate electrical contacts, each electrical connection in the set having a segment extending across a vertical sidewall of the mold compound of at least one of the semiconductor packages.

2. The semiconductor device of claim 1, wherein:
a first segment of a particular electrical connection extends from a first die electrical contact of a first semiconductor die in a first semiconductor package to a first vertical sidewall of the mold compound of the first semiconductor package, the first segment of the particular electrical connection resides within the mold compound of the first semiconductor package; and
a second segment of the particular electrical connection extends from the first segment along the first vertical sidewall of the mold compound of the first semiconductor package and one or more vertical sidewalls of the mold compound of a corresponding one or more additional semiconductor packages to the substrate.

3. The semiconductor device of claim 2, wherein:
the second segment of the particular electrical connection also connects to an additional segment that resides within the mold compound of a second semiconductor package and connects to a second die electrical contact of a second semiconductor die of the second semiconductor package.

4. The semiconductor device of claim 2, wherein:
a third segment of the particular electrical connection extends along the substrate from the second segment to a particular substrate electrical contact.

5. The semiconductor device of claim 1, wherein:
a first segment of a particular electrical connection extends from a first die electrical contact of a first semiconductor die in a first semiconductor package to a first horizontal sidewall of the mold compound of the first semiconductor package, the first segment of the particular electrical connection resides within the mold compound of the first semiconductor package;
a second segment of the particular electrical connection extends from the first segment along the first horizontal sidewall of the mold compound of the first semiconductor package to a vertical sidewall of the mold compound of a second semiconductor package immediately below the first semiconductor package in the stack;
a third segment of the particular electrical connection extends from the second segment along the vertical sidewall of the mold compound of the second semiconductor package and along a vertical sidewall of the mold compound of zero or more additional semiconductor packages to the substrate; and
a fourth segment of the particular electrical connection extends along the substrate from the third segment to a particular substrate electrical contact.

6. The semiconductor device of claim 1, wherein:
a first subset of the segments of the electrical connections that extend across the vertical sidewalls reside on vertical sidewalls of the mold compound of a first subset of the semiconductor packages on a first side of the stack; and
a second subset of the segments that extend across the vertical sidewalls reside on vertical sidewalls of the mold compound of all of the semiconductor packages on a second side of the stack opposite the first side of the stack.

7. The semiconductor device of claim 1, wherein the segments of the electrical connections that extend across the vertical sidewalls reside on vertical sidewalls of the mold compound on the same side of the stack.

8. The semiconductor device of claim 1, further comprising:
a second mold compound that encapsulates the plurality of stacked semiconductor packages, wherein the segments of the electrical connections that extend across the vertical sidewalls of the mold compound of the semiconductor packages are sandwiched between the mold compound of the semiconductor packages and the second mold compound.

9. The semiconductor device of claim 1, further comprising a memory controller configured to control access to memory cells in the semiconductor dies.

10. The semiconductor device of claim 1, wherein:
the semiconductor dies comprises non-volatile memory cells; and
the stack of semiconductor packages resides directly on the substrate.

11. The semiconductor device of claim 1, wherein:
the semiconductor dies comprises non-volatile memory cells; and
the semiconductor device further comprises:
a spacer residing on the substrate between the substrate and the stack of semiconductor packages to support the stack, and
an application specific integrated circuit (ASIC) residing on the substrate in an embedded configuration below the stack of semiconductor packages.

12. A method comprising:
forming a plurality of semiconductor packages, including for each semiconductor package:
attaching a stack of semiconductor dies to a temporary carrier, the stack comprising a plurality of semiconductor dies in an offset configuration with exposed die contacts, each semiconductor die comprising memory cells, the temporary carrier comprising temporary electrical contacts;
forming wire bonds between the die contacts of one or more semiconductor dies in the stack and the temporary electrical contacts;
encapsulating the semiconductor dies with a mold compound, wherein the mold compound encapsulates the wire bonds; and
removing portions of the mold compound to thereby leave wire bond segments in the mold compound with exposed ends of the wire bonds on a first sidewall of the mold compound;
stacking the plurality of semiconductor packages on top of each other on a substrate having a plurality of substrate electrical contacts; and
forming electrical connections between the exposed ends of the wire bonds and the substrate electrical contacts, including forming segments of the electrical connections on the first sidewalls of the mold compound of the plurality of semiconductor packages, the segments connecting to the exposed ends of the wire bonds.

13. The method of claim 12, wherein forming the segments of the electrical connections on the first sidewalls of the mold compound includes:
printing the segments on the first sidewalls of the mold compound.

14. The method of claim 12, wherein forming the segments of the electrical connections on the first sidewalls of the mold compound includes:
dispensing a metallic nanoparticle composition on the first sidewalls of the mold compound.

15. The method of claim 12, wherein:
removing the portions of the mold compound to thereby leave wire bond segments in the mold compound with exposed ends of the wire bonds on the first sidewall of the mold compound includes: dicing the mold compound to form the semiconductor packages having vertical sidewalls of the mold compound, wherein the ends of the wire bonds are exposed on the vertical sidewalls of the mold compound; and
forming the segments of the electrical connections on the first sidewalls of the mold compound of the plurality of semiconductor packages includes dispensing a metallic nanoparticle composition on the vertical sidewalls of the mold compound to connect to the ends of the wire bonds.

16. The method of claim 12, wherein:
removing the portions of the mold compound to thereby leave wire bond segments in the mold compound with exposed ends of the wire bonds on the first sidewall of the mold compound includes forming horizontal sidewalls of the mold compound, wherein the ends of the wire bonds are exposed on the horizontal sidewalls of the mold compound; and
forming the segments of the electrical connections on the first sidewalls of the mold compound of the plurality of semiconductor packages includes dispensing a metallic nanoparticle composition on the horizontal sidewalls of the mold compound to connect to the ends of the wire bonds.

17. A memory system, comprising:
a substrate having a plurality of substrate electrical contacts on a horizontal surface of the substrate;
package stacks residing on the horizontal surface of the substrate, each package stack having a plurality of semiconductor packages above the substrate, wherein each semiconductor package comprises a plurality of semiconductor dies in an offset configuration exposing die electrical contacts, each package stack having a first mold compound encapsulating the plurality of semiconductor dies of the package stack, the first mold compound having vertical sidewalls, each semiconductor die comprising memory cells;
a second mold compound encapsulating the package stacks, the second mold compound having vertical sidewalls adjacent to the vertical sidewalls of the first mold compound; and
electrical connections that connect the die electrical contacts on the semiconductor dies with the substrate electrical contacts, each electrical connection having a segment sandwiched between the vertical sidewall of the first mold compound and the vertical sidewall of the second mold compound.

18. The memory system of claim 17, wherein:
a first segment of a particular electrical connection resides within the first mold compound of a first semiconductor package, the first segment having a first end at a first die electrical contact of a first semiconductor die of the first semiconductor package and a second end at the vertical sidewall of the first mold compound of the first semiconductor package; and
a second segment of the particular electrical connection extends from the second end of the first segment along the vertical sidewall of the first mold compound of the first semiconductor package to the substrate.

19. The memory system of claim 18, wherein a third segment of the particular electrical connection extends along the substrate from the second segment to a particular substrate electrical contact.

20. The memory system of claim 17, further comprising:
a memory controller configured to provide electrical signals to the substrate electrical contacts to control access to the memory cells of the semiconductor dies.
